(19) United States
(12) Patent Application Publication
(10) Pub. No.: US 2025/0091464 A1
(43) Pub. Date: Mar. 20, 2025

(54) ELECTRIC ENERGY ROUTER AND CHARGING STATION

(71) Applicant: Lanto Electronic Limited, Kunshan City (CN)

(72) Inventors: Bin Zhou, Kunshan City (CN); Yuanqiang Gu, Kunshan City (CN); Shuai Li, Kunshan City (CN); Fuqiang Wang, Kunshan City (CN)

(73) Assignee: Lanto Electronic Limited, Kunshan City (CN)

(21) Appl. No.: 18/818,267

(22) Filed: Aug. 28, 2024

(30) Foreign Application Priority Data
Sep. 15, 2023 (CN) 202311196037.1

(51) Int. Cl. B60L 53/62; B60L 53/10; B60L 53/16; B60L 53/22; B60L 53/68; B60L 55/00; H02M 7/00

(52) U.S. Cl. CPC B60L 53/62; B60L 53/11; B60L 53/16; B60L 53/22; B60L 53/68; B60L 55/00; H02M 7/003; B60L 2210/30; B60L 2210/40

(57) ABSTRACT

The present disclosure discloses an electric energy router and a charging station. The electric energy router includes a controller and a plurality of power conversion circuits. Each power conversion circuit converts a first alternating current from a power grid into a first direct current, and feeds the first direct current to a vehicle power supply for charging, the controller monitors current charging power feeding to the vehicle power supply, and the controller controls, in response to determining that the current charging power is greater than a power threshold and a reverse power supply signal is received, the power conversion circuit to convert a second direct current provided by the vehicle power supply into a second alternating current to be feed to the power grid. Thus electric energy can be intelligently distributed. Simultaneous vehicle charging and effective peak load regulation on the grid is achieved, with high flexibility and applicability.

### CLAIM OF PRIORITY AND CROSS-REFERENCE TO RELATED APPLICATION(S)

This application claims the benefit of Chinese Patent Application No. 202311196037.1, filed on Sep. 15, 2023, which is incorporated herein by reference in its entirety.

### BACKGROUND OF THE DISCLOSURE

### 1. Field of the Disclosure

The disclosure relates to the technical field of power electronic devices, in particular to an electric energy router and a charging station.

### 2. Description of the Related Art

While the new energy technology advances increasingly, environmental pollution and energy consumption caused by traditional fuel vehicles escalates. In order to save energy and protect the environment, new energy automobiles (such as electric automobiles) gradually becomes the prevailing routine trip mode of the public. Meanwhile, charging confronts the popularization of the new energy automobiles.

In the prior art, the new energy automobiles are commonly charged through charging stations for extending their ranges. The charging stations can be fixed to the ground or walls of parking lots in public areas (such as public buildings, shopping malls) or residential areas, and charging stations. The charging station is connected to an alternating current power grid and the new energy automobile through its input end and output end respectively. Then it charges the electric automobile after it converts into direct currents electric energy obtained from the alternating current power grid.

The charging station in the prior art has limitations. It is prone to stop charging due to its incapability of flexibly distributing the electric energy in the case of a power shortage of the power grid (for example, the charging stations are undercharged due to a low current load of the power grid). In addition, since numerous new energy automobiles are likely to be connected to the power grid through the charging stations in the prior art during a peak period of power consumption (such as off-duty hours from 5:00 pm to 6:00 pm), a large load peak-to-valley difference of the power grid is caused, and the safety of the power grid is affected adversely.

### BRIEF DESCRIPTION OF THE DISCLOSURE

In view of that, an objective of examples of the disclosure is to provide an electric energy router and a charging station, through which electric energy can be intelligently distributed, vehicle charging, and effective peak load regulation on a power grid are implemented, and high flexibility and applicability are achieved.

In a first aspect, the example of the disclosure provides an electric energy router. The electric energy router includes: a controller; and a plurality of power conversion circuits connected to the controller, where each of the power conversion circuits is configured to convert a first alternating current that is transmitted by a power grid into a first direct current, and transmit the first direct current to a corresponding vehicle power supply for charging; wherein the controller is configured to detect each of the first direct currents to determine current charging power, control, in response to determining that the current charging power is greater than a power threshold and a reverse power supply signal is received, the power conversion circuit to convert a second direct current that is provided by the corresponding vehicle power supply into a second alternating current and transmit the second alternating current to the power grid.

In some examples, the electric energy router further includes: a plurality of bidirectional power supply interfaces, where each of the power conversion circuits is connected to a corresponding bidirectional power supply interface, each of the power conversion circuits includes: an inverter circuit configured to convert the first alternating current into the first direct current, and transmit, through the corresponding bidirectional power supply interface, the first direct current to the corresponding vehicle power supply for charging, or convert the second direct current that is transmitted by the corresponding bidirectional power supply interface into the second alternating current, and the controller is further configured to detect the first direct current that is provided by each of the inverter circuits to determine the current charging power.

In some examples, the controller is further configured to control, in response to determining that the current charging power is greater than the power threshold and the reverse power supply signal is not received, the inverter circuit to output a first direct current that has predetermined power, so as to cause the current charging power to be less than or equal to the power threshold.

In some examples, each of the power conversion circuits further includes: a drive circuit connected to the inverter circuit and the controller; wherein the controller is further configured to control the drive circuit to output a drive signal, to cause the inverter circuit to convert the first alternating current into a corresponding first direct current that has the predetermined power, or cause the inverter circuit to convert the second direct current into the second alternating current.

In some examples, the electric energy router further includes: a transformer that is connected to each of the inverter circuits and the power grid, and configured to perform voltage regulation on the first alternating current that is provided by the power grid, to be transmitted to each of the inverter circuits, or perform voltage regulation on the second alternating current that is provided by the inverter circuit, to be transmitted to the power grid.

In some examples, the electric energy router further includes: a plurality of detection circuits, where each of the detection circuits is connected to the controller and a corresponding power conversion circuit, each of the detection circuits includes: a current detection circuit configured to detect current information of a first direct current that is output by a corresponding inverter circuit and transmit the current information to a signal amplification circuit; a voltage detection circuit configured to detect voltage information of the first direct current that is output by the corresponding inverter circuit, and transmit the voltage information to the signal amplification circuit; and the signal amplification circuit configured to amplify the current information and the voltage information, and transmit the current information and the voltage information that are amplified to the controller; and the controller is further configured to determine the current charging power according to the current information and the voltage information that are amplified.

In some examples, the plurality of power conversion circuits and the transformer are arranged on a first circuit board, and the controller and the plurality of detection circuits are arranged on a second circuit board.

In some examples, the inverter circuit is a half-bridge circuit.

In some examples, the controller is further configured to obtain power supply information and transmit the power supply information to a server, and the power supply information includes at least one of the following information: power supply duration of each of the bidirectional power supply interfaces; the voltage information that is amplified; the current information that is amplified; and alternatively, the current charging power.

In a second aspect, the example of the disclosure provides a charging station. The charging station includes: a monitor; a plurality of charging ports, where each of the charging ports is configured to transmit a first direct current that is provided by an electric energy router to a corresponding vehicle power supply for charging, or transmit a second direct current that is provided by a corresponding vehicle power supply to an electric energy router; an antenna configured to transmit power supply information of the electric energy router to a server; and the electric energy router according to the first aspect.

According to the example of the disclosure, the electric energy router is provided with the controller and the plurality of power conversion circuits. Each of the power conversion circuits converts the first alternating current that is transmitted by the power grid into the first direct current, and transmits the first direct current to the corresponding vehicle power supply for charging. The controller detects the first direct current that is provided by each of the power conversion circuits to determine the current charging power. The controller controls, in response to determining that the current charging power is greater than the power threshold and the reverse power supply signal is received, the power conversion circuit to convert the second direct current that is provided by the corresponding vehicle power supply into the second alternating current and transmit the second alternating current to the power grid. Thus electric energy can be intelligently distributed, vehicle charging, and effective peak load regulation on the power grid are implemented, and high flexibility and applicability are achieved.

### BRIEF DESCRIPTION OF THE DRAWINGS

The above and other objectives, features and advantages of the disclosure will become more apparent from description of examples of the disclosure below with reference to accompanying drawings. In the figures:

FIG. 1 is a circuit diagram of an electric energy router according to an example of the disclosure;

FIG. 2 is an equivalent circuit diagram of an electric energy router according to an example of the disclosure;

FIG. 3 is a circuit diagram of a detection circuit according to an example of the disclosure;

FIG. 4 is a side view of an electric energy router according to an example of the disclosure;

FIG. 5 is an exploded view of a side view of an electric energy router according to the example of the disclosure;

FIG. 6 is a schematic diagram of a charging station according to an example of the disclosure;

FIG. 7 is a schematic diagram of a charging system according to an example of the disclosure; and

FIG. 8 is a schematic diagram of charging a vehicle by a charging station according to an example of the disclosure.

### DESCRIPTION OF REFERENCE NUMERALS

100—charging station;
101—Antenna; 102—monitor; 14a, 14b, 14c—charging port;
10—electric energy router;
10a—first housing; 10a1—connection column;
10b—second housing; 10b1—first via hole; 10b2—second via hole; 10b3—connection portion; 10b4—hollowed portion; 10b5—second connection hole; 10b6—heat dissipation hole;
1—first circuit board;
11, 12, 13, In—power conversion circuit; 11a, 12a, 13a, 1na—inverter circuit; 11b, 12b, 13b, 1nb—drive circuit; 1A1—transformer;
2—second circuit board; 2′—first connection hole; 21—controller; 22, 23, 24, 25—detection circuit; 2a, 2b, 2c, 2n—bidirectional power supply interface;
221—current detection circuit; 222—voltage detection circuit; 223—signal amplification circuit;
3a—connector; 4a, 4b—heat dissipation module; 5—heat dissipation member;
200—server; 3—power grid; 400—photovoltaic generation system;
A, B, C—vehicle; and 14a1, 14b1, 14cl—dedicated charging cable.

### DETAILED DESCRIPTION OF EMBODIMENTS OF THE DISCLOSURE

The disclosure is described below based on examples, but the disclosure is not limited to these examples. In the following detailed description of the disclosure, some specific details are described in detail. The disclosure can be fully understood by those skilled in the art without the description of these details. Well-known methods, processes, flows, elements and circuits are not described in detail in order to avoid obscuring the essence of the disclosure.

In addition, it should be understood by those skilled in the art that the accompanying drawings provided herein are for the purpose of description and are not necessarily drawn to scale.

In addition, it should be understood that in the following description, “circuit” refers to a conductive circuit composed of at least one element or sub-circuit through electrical connection or electromagnetic connection. When an element or a circuit is “connected” to another element or an element/circuit is “connected” between two nodes, the element or the circuit can be directly coupled or connected to another element or through an intermediate element, and a connection between elements can be a physical connection, a logical connection, or their combinations. On the contrary, when an element is “directly coupled” or “directly connected” to another element, it denotes that no intermediate element is arranged therebetween.

Unless otherwise explicitly specified and defined, the terms such as “mount”, “connected”, “connection” and “fix” should be understood broadly, and can denote, for example, fixed connection, detachable connection, integral connection, mechanical connection, electric connection, direct connection, indirect connection through an intermediate medium, communication between interiors of two elements, or interaction between two elements. For those of ordinary skill in the art, specific meanings of the above terms in the disclosure can be understood according to specific circumstances.

For the convenience of description, spatially related terms such as “in”, “out”, “under”, “below”, “lower portion”, “above” and “upper portion” are used herein to describe a relation between one element or feature and another element or feature illustrated in the accompanying drawings. It will be understood that spatially related terms can be intended to include different orientations of the device in use or operation other than those depicted in the accompanying drawings. For example, if the device in the accompanying drawings is turned over, an element described as “below” or “under” other elements or features is positioned “above” the other elements or features. Thus the illustrative term “below” can include above and blow orientations. The device can be oriented in other ways (rotated by 90 degrees or in other orientations), and the spatially related descriptors used herein should be interpreted accordingly.

Unless explicitly specified in the context, similar words such as “comprise” and “include” in the whole disclosure document should be constructed as inclusive rather than exclusive or exhaustive, that is, “comprise but not limited to” and “include but not limited to”.

It should be understood that in the description of the disclosure, the terms “first”, “second”, etc. are merely used for describing purposes and cannot be understood as indicating or implying relative importance. In the description of the disclosure, “plurality” denotes two or more unless otherwise described.

The solutions described in this description and the examples are processed on a legal basis (for example, approved by a subject of personal information, or required by execution of a contract) if processing of personal information is involved, and are merely processed within a specified or agreed scope. The refusal of a user to process personal information other than necessary information for basic functions does not affect use of the basic functions by the user.

The following description is given with an example of a scenario where an electric energy router and a charging station are applied to wired charging of a vehicle power supply of an electric automobile. Specifically, the electric energy router may convert an alternating current that is transmitted by a power grid into a direct current for wired charging of the vehicle power supply of electric automobile. The power grid indicates an entirety composed of substations that have different voltages and power transmission and distribution lines in a power system. The power grid usually has functions of electric energy transmission, electric energy distribution and voltage change, etc. It should be understood that the electric energy router and the charging station in the example of the disclosure may be designed to be applied to various scenarios requiring charging, for example, wired charging of a device to be charged such as an electric bicycle and a mobile power supply, and wireless charging of a device to be charged such as a smart phone and an portable android device.

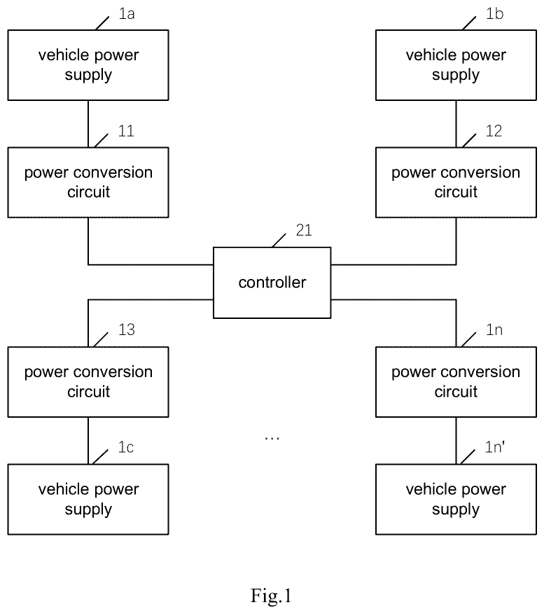

FIG. 1 is a circuit diagram of an electric energy router according to an example of the disclosure. As shown in FIG. 1, the electric energy router of this example includes a plurality of power conversion circuits and a controller 21.

In this example, the plurality of power conversion circuits include 11, 12, 13 and 1n. The power conversion circuits 11, 12, 13 and 1n are connected to the controller 21 and a corresponding vehicle power supply. Specifically, the power conversion circuit 11 is connected to a vehicle power supply 1a. The power conversion circuit 12 is connected to a vehicle power supply 1b. The power conversion circuit 13 is connected to a vehicle power supply 1c. The power conversion circuit 1n is connected to a vehicle power supply 1n′.

In this example, description is given with the electric energy router that includes the plurality of power conversion circuits 11, 12, 13 and 1n as an example. It should be understood that the electric energy router may include one or a plurality of power conversion circuits. A number of power conversion circuits may be set according to demand of the user. For example, a charging station is provided with eight charging positions, and the electric energy router may be provided with eight power conversion circuits. The charging position indicates a geographical area where the electric automobile may be parked for being charged.

In this example, each of the power conversion circuits may convert a first alternating current that is transmitted by a power grid into a first direct current, and transmit the first direct current to a corresponding vehicle power supply for charging. For example, the power conversion circuit 11 converts the first alternating current that is transmitted by the power grid into the first direct current, and transmit the first direct current to the vehicle power supply 1a for charging.

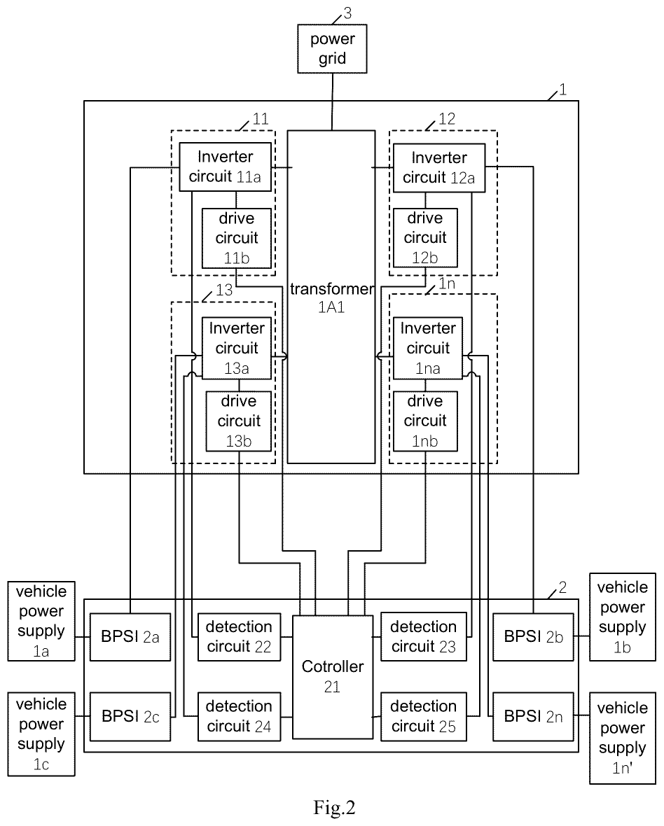

In this example, a charging station in the prior art is caused to stop charging a new energy automobile since the charging station is incapable of flexibly distributing electric energy in the case of a power shortage of the power grid. In addition, since numerous new energy automobiles are connected to the power grid through the charging stations in the prior art during a peak period of power consumption, a large load peak-to-valley difference of the power grid is caused, and safety of the power grid is affected adversely. In view of this situation, in this example, the controller 21 detects in real time the first direct current that is transmitted by each of the power conversion circuits to determine current charging power. Then the controller 21 compares the current charging power with a power threshold. In response to determining that the current charging power is greater than the power threshold and the controller 21 receives a reverse power supply signal, the controller 21 controls a power conversion circuit that corresponds to the reverse power supply signal to convert a second direct current that is provided by the corresponding vehicle power supply into a second alternating current, and transmit the second alternating current to the power grid. Thus electric energy can be intelligently distributed, vehicle charging, and effective peak load regulation on the power grid are implemented, and high flexibility and applicability are achieved. Specifically, reference can be made to FIG. 2 for an equivalent circuit diagram of the electric energy router.

FIG. 2 is an equivalent circuit diagram of an electric energy router according to an example of the disclosure. As shown in FIG. 2, the electric energy router of this example includes a plurality of power conversion circuits, a transformer 1A1, a controller 21, a plurality of detection circuits and a plurality of bidirectional power supply interfaces (BPSI). The plurality of detection circuits 22, 23, 24 and 25 are included. The plurality of bidirectional power supply interfaces 2a, 2b, 2c and 2n are included.

In this example, a failure of the power conversion circuit may be caused since the power conversion circuit may be affected by factors such as environment (for example, a temperature, a humidity and dust), aging (that is, an electronic component that runs for a long time is prone to aging), and voltage fluctuation (for example, voltage fluctuation of the alternating current provided by the power grid). In view of this situation, in this example, the plurality of power conversion circuits and the transformers 1A1 are arranged on a first circuit board 1. And the controller 21, the plurality of detection circuits and the plurality of bidirectional power supply interfaces are arranged on a second circuit board 2. When a power conversion circuit fails, the first circuit board 1 may be replaced for maintenance. Thus the electric energy router is easy to maintain and has high applicability.

Optionally, a plurality of detachable first sub-boards may be arranged on the first circuit board 1, and each of the power conversion circuits is arranged on a corresponding first sub-board. When a power conversion circuit fails, the corresponding first circuit sub-board may be replaced for maintenance. Thus the electric energy router is easy to maintain and has high applicability. The first circuit board 1, each of the first circuit sub-boards and the second circuit board 2 may be printed circuit boards (PCB).

Optionally, the first circuit board 1 may be connected to the second circuit board 2 through a wire, a flat cable, a flexible printed circuit board (FPC), a plurality of PCB connectors, etc. The PCB connector is, for example, a pin connector (that is, a header) of model MR30PB-FB.

In this example, description is given with the condition that the plurality of power conversion circuits and the transformer 1A1 are arranged on the first circuit board 1, and the controller 21, the plurality of detection circuits, and the plurality of bidirectional power supply interfaces are arranged on the second circuit board 2 as an example. It should be understood that the plurality of power conversion circuits, the transformer 1A1, the controller 21, the plurality of detection circuits and the plurality of bidirectional power supply interfaces of this example may be arranged on one circuit board. Thus space of the electric energy router is reduced, a size of the electric energy router is reduced, and applicability of the electric energy router is improved.

In this example, each of the power conversion circuits includes an inverter circuit and a drive circuit. The controller 21 is connected to a corresponding inverter circuit through the drive circuit in each of the power conversion circuits. The drive circuit may be connected to the corresponding inverter circuit through the PCB connector, etc. Specifically, the power conversion circuit 11 includes the inverter circuit 11a and the drive circuit 11b. The controller 21 is connected to the drive circuit 11b. The drive circuit 11b is connected between the controller 21 and the inverter circuit 11a.

The power conversion circuit 12 includes the inverter circuit 12a and the drive circuit 12b. The controller 21 is connected to the drive circuit 12b. The drive circuit 12b is connected between the controller 21 and the inverter circuit 12a.

The power conversion circuit 13 includes the inverter circuit 13a and the drive circuit 13b. The controller 21 is connected to the drive circuit 13b. The drive circuit 13b is connected between the controller 21 and the inverter circuit 13a.

The power conversion circuit 1n includes the inverter circuit 1na and the drive circuit 1nb. The controller 21 is connected to the drive circuit 1nb. The drive circuit 1nb is connected between the controller 21 and the inverter circuit 1na.

In this example, a number of power conversion circuits, a number of detection circuits and a number of bidirectional power supply interfaces of the electric energy router are the same. That is, each of the power conversion circuits is correspondingly provided with the detection circuit and the bidirectional power supply interface, and the inverter circuit in each of the power conversion circuits is connected to a corresponding detection circuit and bidirectional power supply interface.

Optionally, each of the power conversion circuits has a preset positional relation with the corresponding bidirectional power supply interface and detection circuit. For example, the power conversion circuit 11 of the first circuit board 1 has the preset positional relation with the detection circuit 22 and the bidirectional power supply interface 2a of the second circuit board 2. Thus wiring difficulty can be reduced and the applicability of the electric energy router can be improved.

In this example, the inverter circuit of the power conversion circuit is connected to the corresponding detection circuit and bidirectional power supply interface, and the transformer 1A1. The controller 21 is connected to the inverter circuits in corresponding power conversion circuits through each of the detection circuits. Specifically, the inverter circuit 11a is connected to the bidirectional power supply interface 2a, the detection circuit 22 and the transformer 1A1. The controller 21 is connected to the inverter circuit 11a through the detection circuit 22.

The inverter circuit 12a is connected to the bidirectional power supply interface 2b, the detection circuit 23 and the transformer 1A1. The controller 21 is connected to the inverter circuit 12a through the detection circuit 23.

The inverter circuit 13a is connected to the bidirectional power supply interface 2c, the detection circuit 24 and the transformer 1A1. The controller 21 is connected to the inverter circuit 13a through the detection circuit 24.

The inverter circuit 1na is connected to the bidirectional power supply interface 2n, the detection circuit 25 and the transformer 1A1. The controller 21 is connected to the inverter circuit 1na through the detection circuit 25.

In this example, the transformer 1A1 is connected to the power grid 3 and the inverter circuit in each of the power conversion circuits.

In this example, the power conversion circuits, that is, the power conversion circuits 11, 12, 13 and 1n, have the same circuit structure. The detection circuits, that is, the detection circuits 22, 23, 24 and 25, has the same circuit structure. The following description is given with the power conversion circuit 11, the detection circuit 22 and the bidirectional power supply interface 2a as examples.

Optionally, each of the bidirectional power supply interfaces is connected to a corresponding charging interface, and the charging interface may charge the vehicle power supply of the electric automobile through a charging gun or a dedicated charging cable. The charging interface is adapted to the charging gun or the dedicated charging cable.

In this example, each of the bidirectional power supply interfaces may adopt a dedicated power supply interface. For example, each of the bidirectional power supply interfaces may be designed according to charging power required by a device to be charged (such as the electric automobile). Each of the bidirectional power supply interfaces may transmit the direct current that is provided by the corresponding inverter circuit to the corresponding vehicle power supply for charging. Each of the bidirectional power supply interfaces may further transmit the direct current that is provided by the vehicle power supply to the corresponding inverter circuit.

In this example, the controller 21 may be an electronic device that has functions of data processing, data storage, data transmission, etc. The controller 21 may adopt a microcontroller unit (MCU), for example, the MCU of model STM32H7.

Optionally, the controller 21 may further adopt a programmable logic controller (PLC), a field-programmable gate array (FPGA), a digital signal processor (DSP) or an application specific integrated circuit (ASIC).

In this example, each of the drive circuits may adopt a microelectronic component, that is, an integrated circuit chip (IC), for example, a chip of model 2EDF7235K. The controller 21 may send a control signal to a drive circuit, and the drive circuit is caused to output a drive signal corresponding to the control signal accordingly. Further, the drive circuit transmits the drive signal to the corresponding inverter circuit, the inverter circuit may convert the first alternating current that is transmitted by the transformer 1A1 into the first direct current, or the inverter circuit may convert the second direct current that is transmitted, through the corresponding bidirectional power supply interface, by the corresponding vehicle power supply into the second alternating current. The control signal is, for example, a pulse width modulation (PWM) signal. The drive signal includes a high level signal and a low level signal.

In this example, the inverter circuit may adopt a half-bridge inverter circuit or a full-bridge inverter circuit.

Optionally, each of the inverter circuits may include a plurality of high-frequency switch elements. The high-frequency switch element may adopt a transistor, such as a metal oxide semiconductor field-effect transistor (MOSFET) and an insulated gate bipolar transistor (IGBT). The high-frequency switch element may be turned on under the control of the high-level signal of the drive signal and may be turned off under the control of the low-level signal of the drive signal. That is, the controller 21 may drive, through the drive circuit, each of the high-frequency switch elements of the corresponding inverter circuit to be in different turn-on and turn-off states at high frequencies. That is, the circuit is switched between connection or disconnection continuously, the inverter circuit may convert the first alternating current into the first direct current, or the inverter circuit may convert the second direct current into the second alternating current.

In this example, the controller 21 may control the drive circuit to output the drive signal, so as to drive the high-frequency switch element of the corresponding inverter circuit to be in the turn-on and turn-off states at different frequencies. Thus the inverter circuit may generate direct currents or alternating currents that have different electric parameters such as a power value and a voltage value. That is, the controller 21 may control power at which the electric energy router charges the electric automobile.

Optionally, each of the inverter circuits may further include an input filter circuit and an output filter circuit. The input filter circuit and the output filter circuit may adopt capacitors, resistors, diodes, etc. The input filter circuit may filter the first alternating current that is transmitted by the transformer 1A1 to remove possible noise and interference. Then the first alternating current filtered is converted into the first direct current through the high-frequency switch element. The input filter circuit may further filter the second direct current that is transmitted by the corresponding vehicle power supply through the corresponding bidirectional power supply interface. Then convert the second direct current filtered is converted into the second alternating current through the high-frequency switch element. Correspondingly, the output filter circuit may filter the first direct current. Then the first direct current filtered is transmitted through the corresponding bidirectional power supply interface to the corresponding vehicle power supply for charging. The output filter circuit may further filter the second alternating current. Then the second alternating current filtered is transmitted to the power grid 3 through the transformer 1A1.

In this example, the transformer 1A1 may adopt a planar transformer (PT), and is configured to perform voltage regulation on the first alternating current to be subjected to voltage regulation that is transmitted by the power grid 3. Then the first alternating current subjected to voltage regulation is transmitted to the inverter circuit of each of the power conversion circuits. Alternatively, the transformer 1A1 may perform voltage regulation on the second alternating current that is transmitted by the inverter circuit of the power conversion circuit. Then the second alternating current subjected to voltage regulation is transmitted to the power grid 3 for peak load regulation.

Optionally, the transformer 1A1 may include a primary winding and a secondary winding, and a ratio of the primary winding to the secondary winding is predetermined. Thus the first alternating current to be subjected to voltage regulation that is transmitted by the power grid 3 or the second alternating current that is transmitted by the inverter circuit of the power conversion circuit is boosted or bucked, and the voltage regulation function is implemented. Further, the transformer 1A1 may further include a core, and the core may be arranged between the primary winding and the secondary winding. Thus transmission efficiency and stability of electric energy between the primary winding and the secondary winding are improved. The core is, for example, ferroxcube of E58/11/38 and PLT58/38/4.

Optionally, the primary winding and the secondary winding of the transformer 1A1 may be wound by adopting multi-layers PCBs, and then each layer of PCBs is connected to the corresponding inverter circuit. That is, the transformer 1A1 may provide the first alternating current of the same voltage value for each of the inverter circuits. The transformer 1A1 may further provide the first alternating currents of different voltage values for each of the inverter circuits.

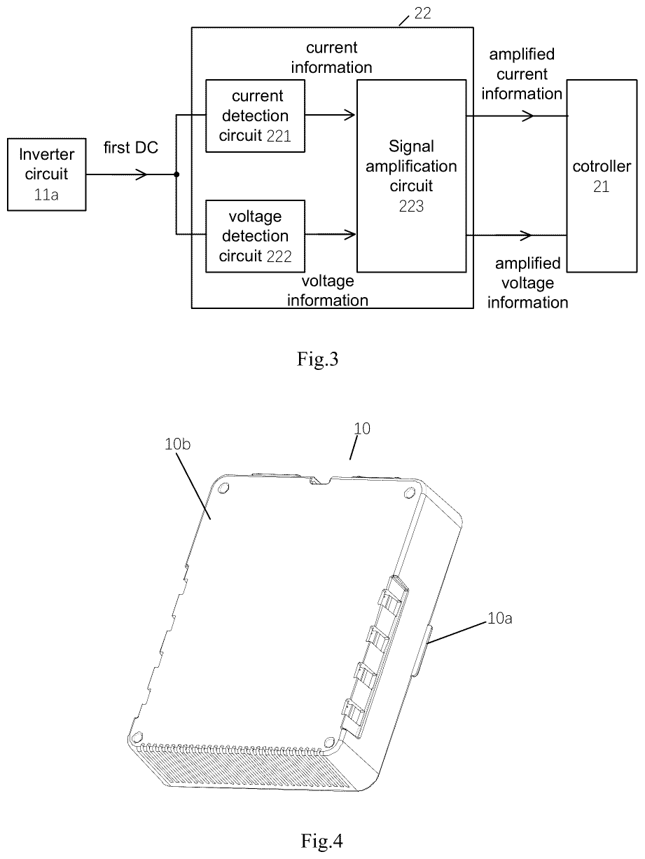

In this example, the controller 21 may detect the first direct current that is transmitted by each of the inverter circuits through each of the detection circuits to determine the current charging power. Each of the detection circuits includes a current detection circuit, a voltage detection circuit and a signal amplification circuit. In the following description, the detection circuit 22 and the inverter circuit 11a are taken as examples, and reference can be made to FIG. 3 for a circuit diagram of the detection circuit of this example.

FIG. 3 is a circuit diagram of a detection circuit according to an example of the disclosure. As shown in FIG. 3, the detection circuit 22 of this example includes the current detection circuit 221, the voltage detection circuit 222 and the signal amplification circuit 223. The inverter circuit 11a is connected to a current detection circuit 221 and a voltage detection circuit 222. The current detection circuit 221 is connected between the inverter circuit 11a and the signal amplification circuit 223. The voltage detection circuit 222 is connected between the inverter circuit 11a and the signal amplification circuit 223. The signal amplification circuit 223 is connected to the current detection circuit 221, the voltage detection circuit 222 and the controller 21.

In this example, the current detection circuit 221, the voltage detection circuit 222 and the signal amplification circuit 223 may adopt different microelectronic components. The current detection circuit 221 is, for example, a current sensor of model TMCS1100A3QDR. The voltage detection circuit 222 is, for example, a voltage sensor of model ACPL-C87H-500E. The signal amplification circuit 223 is, for example, an operational amplifier of model LM258D. And TMCS1100A3QDR is an electrically isolated Hall effect current sensor, can measure a current of the direct current or the alternating current, and has high accuracy, excellent linearity and temperature stability. In addition, TMCS1100A3QDR has a low error rate. The ACPL-C87H-500E is an optically isolated voltage sensor, and can accurately measure voltage information.

Optionally, the current detection circuit 221 may further adopt current sensors of model ACS780xLR and model ACS770. The voltage detection circuit 222 may further adopt a potential transformer, a Hall voltage sensor, etc.

Optionally, the electric energy router may further include one or more wireless transmitter coils and receiver coils, and the wireless transmitter coils are connected to the transformer 1A1. The wireless transmitter coil is configured to wirelessly charge a corresponding device to be charged, and the device to be charged is a mobile phone, an electric automobile, etc. That is, a peak load regulation mode in this example is further applicable to a wireless charging scenario, etc. For example, the transformer 1A1 performs voltage regulation on the first alternating current that is provided by the power grid 3, and sends, through the transmitter coil, the first alternating current subjected to voltage regulation to the electric automobile for wireless charging. The controller 21 detects each of the first direct currents and each of the first alternating currents subjected to voltage regulation to determine the current charging power. In response to determining that the current charging power is greater than the power threshold, and the reverse power supply signal is received, the controller 21 controls the power conversion circuit to convert the second direct current that is provided by the corresponding vehicle power supply into the second alternating current and transmit the second alternating current to the power grid 3. In addition, the controller controls the receiver coil to perform, through the transformer 1A1, voltage regulation on the alternating current that is provided by the transmitter coil of the electric automobile and transmit the alternating current subjected to voltage regulation to the power grid 3.

In this example, when the inverter circuit 11a converts the first alternating current that is transmitted by the transformer 1A1 into the first direct current, and then the inverter circuit 11a transmits, through the bidirectional power supply interface 2a, the first direct current to the vehicle power supply for charging, the current detection circuit 221 may detect current information of the first direct current that is output by the corresponding inverter circuit 11a, and then the current detection circuit 221 transmits the current information to the signal amplification circuit 223. In addition, the voltage detection circuit 222 may detect voltage information of the first direct current that is output by the inverter circuit 11a, and then the voltage detection circuit 222 outputs the voltage information to the signal amplification circuit 223. Further, the signal amplification circuit 223 amplifies the current information and the voltage information to obtain the current information and the voltage information that are amplified. Then the signal amplification circuit 223 transmits the current information and voltage information that are amplified to the controller 21. The controller 21 may determine power information of the first direct current that is output by the inverter circuit 11a according to the current information and the voltage information that are amplified. Similarly, the controller 21 may determine, through the detection circuits 23, 24 and 25, power information corresponding to the first direct currents that are output by the inverter circuits 12a, 13a and Ina respectively. Further, the controller 21 may determine the current charging power according to the power information corresponding to the first direct current that is output by each of the inverter circuits.

In this example, the controller 21 may compare the current charging power with the power threshold, so as to determine whether to convert the second direct currents that are provided by the vehicle power supplies of some electric automobiles into the second alternating currents and transmit the second alternating currents to the power grid 3 for peak load regulation. The case that the current charging power is less than or equal to the power threshold indicates that a total power value at which the electric energy router charges each of the electric automobiles at a current moment is less than or equal to the power threshold. The case that the current charging power is greater than the power threshold indicates that a total power value at which the electric energy router charges each of the electric automobiles at a current moment is greater than the power threshold, and then indicates that the electric energy router may obtain, from the power grid 3, electric energy that exceeds the power threshold. Thus a load of the power grid 3 may be caused to increase and stability and safety of the power grid 3 are affected. In this case, the controller 21 needs to adjust the charging power at which each of the electric automobiles is charged, that is, power of the first direct current that is output by each of the inverter circuits, so as to reduce the current charging power to be less than the power threshold.

In this example, the power threshold may be determined based on electricity distribution power. The electricity distribution power indicates the power consumption power that is distributed to the electric energy router by the power grid 3.

In an optional embodiment, the power threshold is equal to the electricity distribution power. In this case, more charging positions may be configured for the electric energy router, such that the electric energy router can charge more electric automobiles.

In another optional embodiment, the power threshold is less than the electricity distribution power, and the electricity distribution power and the power threshold have a predetermined difference. That is, in consideration of the fact that the current charging power may exceed the power threshold, the power threshold is set to be less than the electricity distribution power in order to improve the safety and stability of the power grid 3. Thus when the current charging power is greater than the power threshold, the current charging power is less than the electricity distribution power.

In this example, if the current charging power is less than or equal to the power threshold, the controller 21 may provide a corresponding drive signal through each of the drive circuits. Each corresponding inverter circuit is caused to convert the first alternating current that is transmitted by the transformer 1A1 into the first direct current and transmit the first direct current to the corresponding vehicle power supply for charging.

In this example, the controller 21 may obtain the power supply information corresponding to each of the electric automobiles, and then transmit the power supply information to the server for being stored. The power supply information includes power supply duration of each of the bidirectional power supply interfaces, the voltage information and the current information that are amplified of the first direct current that is provided by each of the inverter circuits, and the current charging power.

Optionally, the server may parse and compute the power supply information to obtain electricity consumption data (for example, an electricity consumption quantity and the current charging power) of a corresponding electric energy router. Then the server feeds back the electricity consumption data to the power grid 3.

Optionally, the server may compare the current charging power of the electric energy router with the electricity distribution power to determine a electricity distribution request. The electricity distribution request includes the current charging power of the electric energy router. Then the server sends the electricity distribution request to the power grid 3, to cause the power grid 3 to adjust the electricity distribution power of the electric energy router according to the electricity distribution request. For example, the current charging power of the electric energy router is less than or equal to the power threshold, and the server sends the electricity distribution request to the power grid 3, to cause the power grid 3 to reduce the electricity distribution power of the electric energy router. For example, the current charging power of the electric energy router is greater than the power threshold, and the server sends the electricity distribution request to the power grid 3, to cause the power grid 3 to increase the electricity distribution power of the electric energy router. Thus the electricity distribution power of the electric energy router can be dynamically adjusted, power consumption demand of different electric energy routers is satisfied and the flexibility and applicability of electric energy distribution are improved.

Optionally, the power supply information further includes user information corresponding to each of the electric automobiles. The user information may include a user identifier, an account number, a mobile phone number, an identifier of an application program or an applet that is related to the electric energy router in the mobile phone of the user, a user recharge amount, etc. Further, the power supply information further includes a total electricity consumption quantity of each of the electric automobiles within a predetermined period, a utilization rate of the bidirectional power supply interface within the predetermined period (that is, the ratio of a number of bidirectional power supply interfaces for charging the vehicle power supply to a total number of bidirectional power supply interfaces), etc.

Optionally, if the current charging power is less than or equal to the power threshold, the server may dynamically adjust the electricity distribution power of the corresponding electric energy router through the power grid 3 according to the current charging power of each of the electric energy routers. For example, if the current charging power of a first electric energy router is less than first electricity distribution power, the server reduces the first electricity distribution power of the first electric energy router to the current charging power through the power grid 3, and determines reserved power. The reserved power denotes a difference between the first electricity distribution power and the current charging power. Then the server may distribute, through the power grid 3, the reserved power to other electric energy routers whose current charging power is greater than the electricity distribution power. Thus the server can dynamically adjust the electricity distribution power, and high applicability and flexibility are achieved.

Optionally, if the current charging power is less than or equal to the power threshold, each of the power conversion circuits has different power levels. That is, the controller 21 may control, through each of the drive circuits, each corresponding inverter circuit to output the first direct currents that have different power values. The power level indicates the power value of the first direct current.

In an optional embodiment, the power level may be determined based on an application scenario of the electric energy router. For example, when the electric energy router is configured to charge the electric automobile, the controller 21 may determine the power level according to the charging power required by the vehicle power supply of the electric automobile. The power level may include 15 kw, 20 kw, 30 kw, 40 kw, 45 kw, 60 kw, 75 kw, 80 kw, 120 kw, etc.

In another optional embodiment, the power level may be determined based on a user level. The controller 21 may obtain the user information of the electric automobile to determine a corresponding user level. The user level may be determined according to historical charging duration, a total historical charging quantity, registration duration, etc. of the electric energy router. For example, the user level includes an unregistered user, a registered user, an ordinary member, a senior member, etc. A power level of the senior member is greater than a power level of the ordinary member, the power level of the ordinary member is greater than a power level of the registered user, and the power level of the registered user is greater than a power level of the unregistered user. When the electric automobile is connected to the electric energy router, the controller 21 may obtain the user information of the electric automobile, and then the controller 21 sends the user information to the server. The server may determine a corresponding user level according to the historical charging duration, the total historical charging quantity and the registration duration that are stored, and feed the user level back to the controller 21.

In yet another optional embodiment, the power level may be determined based on a power signal. The controller 21 may determine a corresponding power level according to the power value indicated by the power signal received. For example, if the user wants quick charging, the user may send the power signal to the controller 21 through an application program or applet associated with the electric energy router in the mobile phone. Then the controller 21 may control the corresponding inverter circuit to provide the first direct current that has high power through the drive circuit. For example, the electric energy router is arranged in the charging station, and the charging station is equipped with a monitor; (such as a touch screen). Thus the user may input required charging power through the monitor to determine the power signal.

In this example, if the controller 21 detects that the current charging power is greater than the power threshold, the controller 21 needs to adjust the charging power of each of the electric automobiles, that is, the power of the first direct currents that are output by some inverter circuits, and/or control some other inverter circuits to convert the second direct current that is provided by the vehicle power supply into the second alternating current and transmit the second alternating current to the power grid 3. In this way, the current charging power is reduced to be less than the power threshold.

In this example, in response to determining that the current charging power is greater than the power threshold and the controller 21 receives the reverse power supply signal, the controller 21 controls the power conversion circuit that corresponds to the reverse power supply signal to convert the second direct current that is provided by the corresponding vehicle power supply into the second alternating current. Then the power conversion circuit transmits the second alternating current to the transformer 1A1, and the second alternating current is subjected to voltage regulation by the transformer 1A1 and then transmitted to the power grid 3 for peak load regulation. The controller 21 may obtain, through the corresponding detection circuit, the power information of the second direct current that is provided by the vehicle power supply, and compute according to the first direct current that is provided by each of the inverter circuits to determine the current charging power. That is, if the current charging power is greater than the power threshold, some inverter circuits convert the second direct current that is provided by the corresponding vehicle power supply into the second alternating current for peak load regulation for the power grid 3, and some other inverter circuits convert the first alternating current that is transmitted by the transformer 1A1 into the first direct current for charging the corresponding vehicle power supply. Thus the controller may determine the current charging power according to a difference between the power value of each of the first direct currents and a power value of each of the second direct currents.

In an optional embodiment, after the controller 21 detects that the current charging power is greater than the power threshold, the controller 21 may send a reverse power supply request signal to the application program or applet (such as the mobile phone) of a user terminal corresponding to each of the electric automobiles. The corresponding application program or applet in the user terminal may display the reverse power supply request signal through a pop-up window, a prompt column etc. If the user agrees about reverse power supply, that is, the controller 21 receives the reverse power supply signal that is sent by the user terminal, the inverter circuit for charging the electric automobile of the user is controlled to convert the second direct current that is provided by the corresponding vehicle power supply into the second alternating current.

Optionally, the controller 21 may obtain electric quantity information of the vehicle power supply of each of the electric automobiles in real time. Then the controller 21 compares the electric quantity information with a first electric quantity threshold. The case that the electric quantity information is greater than the first electric quantity threshold indicates that the vehicle power supply may perform peak load regulation on the power grid 3, and the controller 21 sends a reverse power supply request signal to the user terminal corresponding to the electric automobile that has the electric quantity information greater than the first electric quantity threshold. If the electric quantity information is less than or equal to the first electric quantity threshold, the controller 21 does not need to send a reverse power supply request signal to the user terminal corresponding to the electric automobile that has the electric quantity information less than or equal to the first electric quantity threshold, and continues charging the vehicle power supply of the electric automobile. For example, the case that the first power threshold is, for example, 70% and the electric quantity information of the vehicle power supply is 100% indicates that the vehicle power supply is fully charged, and the controller 21 may send the reverse power supply request signal to the user terminal of the electric automobile corresponding to the vehicle power supply.

Further, the case that the controller 21 detects that the electric quantity information of the vehicle power supply of the electric automobile that provides the second direct current is less than or equal to a second electric quantity threshold indicates that the vehicle power supply cannot perform peak load regulation for the power grid 3. Then the controller 21 controls the inverter circuit corresponding to the vehicle power supply to convert the first alternating current that is transmitted by the transformer 1A1 into the first direct current for charging the vehicle power supply. That is, since the electric quantity of the vehicle power supply decreases after the vehicle power supply reversely supplies power to the power grid 3, the electric energy router continues to charge the vehicle power supply after the electric quantity information of the vehicle power supply is lower than the second electric quantity threshold. The second electric quantity threshold is less than or equal to the first electric quantity threshold, and the second electric quantity threshold is, for example, 40%.

Optionally, if the controller 21 receives a reverse power supply stop signal for the vehicle power supply of the electric automobile that provides the second direct current, the controller 21 controls the inverter circuit corresponding to the vehicle power supply to convert the first alternating current that is transmitted by the transformer 1A1 into the first direct current for charging the vehicle power supply. For example, the user may send the reverse power supply stop signal to the controller 21 through the application program or applet of the terminal, and then the electric energy router continues to charge the vehicle power supply.

In yet another optional embodiment, the user may determine, through setting in the application program or applet of the terminal, whether the corresponding vehicle power supply performs reverse power supply. If the user sets reverse power supply, the application program or applet sends a reverse power supply confirmation instruction on the electric automobile to the server. Further, during a charging process of the electric automobile, if the server determines that the current charging power of the electric energy router is greater than the power threshold or electricity distribution power, the server sends the reverse power supply signal of the electric automobile to the controller 21, and the controller 21 is caused to control the corresponding power conversion circuit to convert the second direct current that is provided by the vehicle power supply of the electric automobile into the second alternating current and transmit the second alternating current to the power grid 3 for peak load regulation.

In yet another optional embodiment, the user may determine, through setting on the monitor of the charging station, whether the corresponding vehicle power supply performs reverse power supply. If the user sets the reverse power supply, the monitor sends a reverse power supply signal of the electric automobile to the controller 21, and after the controller 21 detects that the current charging power is greater than the power threshold, peak load regulation is performed through the second direct current that is provided by the vehicle power supply of the electric automobile.

Optionally, for the user of the electric automobile that provides the second direct current, the controller 21 may compute a corresponding power supply quantity according to the power, the power supply duration, etc. of the second direct current that is provided by the vehicle power supply of the electric automobile. Then the controller 21 converts the power supply quantity into free charging duration and a monetary amount of the user and/or an upgrade of the user level of the user.

In this example, if the current charging power is greater than the power threshold and the controller 21 does not receive a reverse power supply signal, the controller 21 controls each of the power conversion circuits that does not receive the reverse power supply signal to output the first direct current that has the same or different predetermined power, and the current charging power is caused to be less than or equal to the power threshold. That is, if the current charging power is greater than the power threshold, for the corresponding vehicle power supply that receives the reverse power supply signal, the controller 21 controls the corresponding power conversion circuit to convert the second direct current that is provided by the vehicle power supply into the second alternating current and transmit the second alternating current to the power grid. In addition, for the corresponding vehicle power supply that does not receive the reverse power supply signal, the controller 21 adjusts the charging power of the vehicle power supply through the corresponding power conversion circuit, and the current charging power of the electric energy router is caused to be less than or equal to the power threshold. Thus the electric energy router can intelligently distribute electric energy, vehicle charging, and effective peak load regulation on the power grid are implemented, and high flexibility and applicability are achieved. The following description is given with each of the power conversion circuits outputting the first direct current that has different predetermined power as an example.

Optionally, the predetermined power is determined based on the user level. For example, the user level includes the unregistered user, the registered user, the ordinary member, the senior member, etc. Predetermined power of the senior member is greater than predetermined power of the ordinary member, the predetermined power of the ordinary member is greater than predetermined power of the registered user, and the predetermined power of the registered user is greater than predetermined power of the unregistered user. That is, the higher the user level, the higher the corresponding predetermined power is. It is easy to understand that the predetermined power at which the electric energy router provides the first direct current for a vehicle power supply when the current charging power is greater than the power threshold is less than or equal to the charging power at which the first direct current is provided for the vehicle power supply when the current charging power is less than or equal to the power threshold. For example, when the current charging work is less than or equal to the power threshold, the charging power at which the electric energy router provides the first direct current for the vehicle power supply G1 of the electric automobile G is G11. When the current charging power is greater than the power threshold, the predetermined power at which the electric energy router provides the first direct current for the vehicle power supply G1 is G12. A power value indicated by G12 is less than a power value indicated by G11.

In an optional embodiment, the controller 21 may send the user information of the electric automobile to the server, and then determine the user level of the electric automobile according to feedback information of the server. After the electric automobile is connected to the electric energy router, the controller 21 may obtain the user information of the electric automobile. For example, after the bidirectional power supply interface 2a is connected to the vehicle power supply 1a through a charging gun, the controller 21 detects a charging signal (such as a connection confirm (CC) signal and a control press (CP) signal), etc. Then the controller 21 may obtain the corresponding user information through a microcontroller unit (MCU) of the electric automobile, and then charge the electric automobile.

In another optional embodiment, the user information of the electric automobile includes the user level. The controller 21 directly determines the corresponding user level after analyzing the user information.

Optionally, the predetermined power may further be determined based on a predetermined power signal. For example, if the user wants quick charging, the user may send the predetermined power signal to the controller 21 through the application program or applet associated with the electric energy router in the mobile phone. Then the controller 21 may determine the corresponding predetermined power according to the predetermined power signal received. Further, the controller 21 controls an inverter circuit that corresponds to the predetermined power signal to provide the first direct current that has the predetermined power, so as to charge the vehicle power supply of the electric automobile of the user.

Optionally, the predetermined power may further be determined by the controller 21 based on the power threshold. That is, each of the power conversion circuits is adjusted to output the first direct current that has the corresponding predetermined power, and the current charging power of the electric energy router is caused to be less than or equal to the power threshold.

In this example, the electric energy router further includes a photovoltaic interface. The transformer 1A1 of the electric energy router may further be connected to an external photovoltaic generation system (PGS) through a photovoltaic interface. The photovoltaic generation system includes, for example, a stand alone photovoltaic (PV) system and a grid connected PV system. Specifically, the photovoltaic generation system may provide an alternating current for the electric energy router. The electric energy router performs voltage regulation on the alternating current through the transformer 1A1 and transmit the alternating current subjected to voltage regulation to the inverter circuit of each of the power conversion circuits. Then the inverter circuit converts the alternating current subjected to voltage regulation into the first direct current for supplying power to the vehicle power supply. Thus when the current charging power is greater than the power threshold, some vehicle power supplies may be charged by the photovoltaic generation system, and a power consumption peak value of the power grid 3 can be further reduced. The controller 21 may compute the current charging power according to the power of each of the first direct currents converted from the first alternating currents that are provided by the power grid 3, the power of each of the first direct currents converted from the alternating currents that are provided by the photovoltaic generation system and the power of the second direct current that is provided by the vehicle power supply.

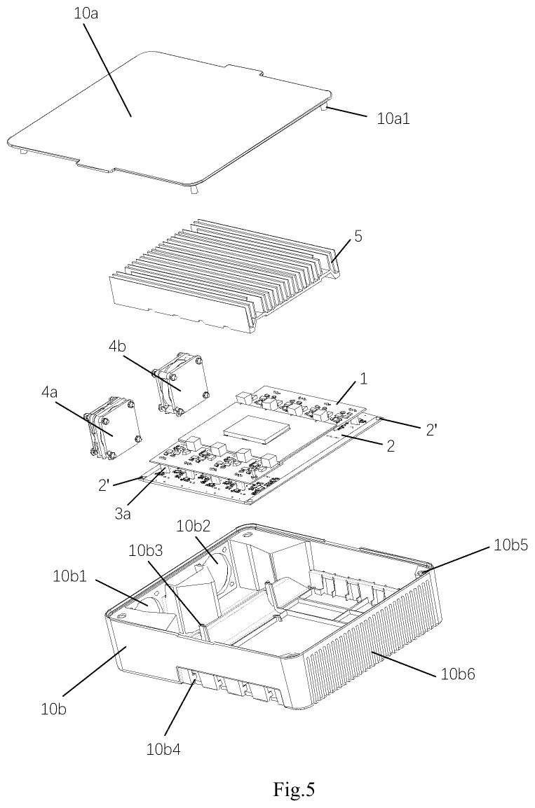

Optionally, the electric energy router further includes a power supply circuit, and the power supply circuit may be arranged on the second circuit board 2. Specifically, the power supply circuit is connected to a standby power supply (for example, a storage battery), and in addition, the power supply circuit is connected to the controller 21, etc. of the electric energy router. The standby power supply may supply power to each of components of the electric energy router through the power supply circuit in the case of outage, and the controller 21 is caused to transmit the power supply information to the server. The power supply circuit may adopt a power supply management chip of model LM5010MH_NOPB. Further, reference can be made to FIG. 4 and FIG. 5 for a side view and an exploded view of the electric energy router respectively.

FIGS. 4 and 5 are the side view and the exploded view of the electric energy router according to the example of the disclosure. As shown in FIGS. 4 and 5, the electric energy router 10 of this example includes a first housing 10a, a second housing 10b, a first circuit board 1, a second circuit board 2, a plurality of connectors 3a, a plurality of heat dissipation modules 4a and 4b and a heat dissipation member 5. The first housing 10a includes a plurality of connection columns 10a1. The second circuit board 2 includes a plurality of first connection holes 2′. The second housing 10b includes a first via hole 10b1, a second via hole 10b2, a plurality of connection portions 10b3, a plurality of hollowed portions 10b4, a plurality of second connection holes 10b5 and a heat dissipation hole 10b6.

In this example, the plurality of connection columns 10al of the first housing 10a are arranged corresponding to the plurality of second connection holes 10b5 of the second housing 10b. Then the first housing 10a and the second housing 10b may be fixed by means of screws, bolts, rivets, etc.

In this example, the plurality of first connection holes 2′ of the second circuit board 2 are arranged corresponding to the plurality of connection portions 10b3 of the second housing 10b. Then the second circuit board 2 may be arranged in the second housing 10b by means of screws, bolts, rivets, etc.

In this example, the second circuit board 2 is connected to the first circuit board 1 through the plurality of connectors 3a. Then the first circuit board 1 is fixed above the second circuit board 2. The connector 3a is, for example, a pin connector (that is, a header) of model MR30PB-FB.

In this example, the heat dissipation member 5 is arranged between the first circuit board 1 and the first housing 10a. The heat dissipation member 5 may be fixed to a surface, facing the first housing 10a, of the first circuit board 1 by means of screws, bolts, rivets, etc. Further, the heat dissipation member 5 includes a plurality of heat dissipation fins arranged at intervals, thus heat dissipation efficiency can be improved.

In this example, the heat dissipation module 4a is adapted to the first via hole 10b1, and the heat dissipation module 4a may be fixed into the first through hole 10b1 by means of screws, bolts etc. Correspondingly, the heat dissipation module 4b is adapted to the second via hole 10b2, and the heat dissipation module 4b may be fixed into the second via hole 10b2 by means of screws, bolts, etc. The heat dissipation modules 4a and 4b may include components such as fans and are configured to perform heat dissipation on the electric energy router 10.

In this example, the heat dissipation hole 10b6 includes a plurality of heat dissipation sub-holes provided at intervals and is configured to perform heat dissipation on the electric energy router 10.

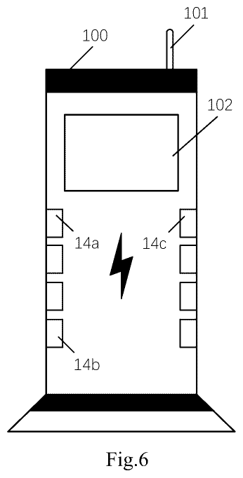

In this example, the plurality of hollowed portions 10b4 in the second housing 10b are adapted to the plurality of bidirectional power supply interfaces provided in the second circuit board 2. In this way, each of the bidirectional power supply interfaces may penetrate a corresponding hollowed portion, to be connected to the charging interface corresponding to the charging station. Further, reference can be made to FIG. 6 for the charging station of this example.

FIG. 6 is a schematic diagram of a charging station according to an example of the disclosure. As shown in FIG. 6, the charging station 100 of this example includes an antenna 101, a monitor 102, a plurality of charging ports 14a, 14b and 14c, and an electric energy router 10.

In this example, the charging ports 14a, 14b and 14c are connected to the bidirectional power supply interfaces 2a, 2b and 2c of the electric energy router 10 respectively. Meanwhile, the charging ports 14a, 14b and 14c may be connected to the vehicle power supply of the corresponding electric automobile through charging guns or dedicated charging cables, so as to charge the corresponding electric automobile.

In this example, the monitor 102 is connected to the controller 21 of the electric energy router 10.

Optionally, the user may interact with the monitor 102, so as to perform the functions of login, registration, user level query, predetermined amount recharging, required charging power input, reverse power supply setting, etc.

Optionally, the charging station 100 further includes a standby power supply. The standby power supply is connected to the power supply circuit of the electric energy router 10 and configured to supply power to each of components of the electric energy router through the power supply circuit in the case of outage, and the controller 21 is caused to transmit the power supply information to the server.

In this example, the antenna 101 is connected to the controller 21 of the electric energy router 10. The controller 21 may transmit the power supply information of the electric energy router to the server through the antenna 101.

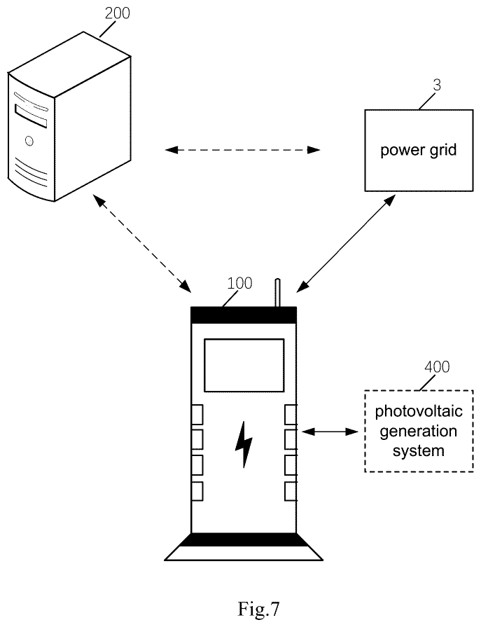

Optionally, the electric energy router 10 may further be provided with a communication module, and the communication module is connected to the controller 21 and the antenna 101. The controller 21 transmits the power supply information to the server through the communication module and the antenna 101. Further, reference can be made to FIG. 7 for a schematic diagram of a charging system of this example.

FIG. 7 is a schematic diagram of a charging system according to an example of the disclosure. As shown in FIG. 7, the charging system of this example includes a charging station 100, a server 200 and a power grid 3. The power grid 3 is connected to the transformer 1A1 of the electric energy router 10 in the charging station 100. The controller 21 of the electric energy router 10 of the charging station 100 may be in communication connection to the server 200 through the antenna 101. The server 200 is in communication connection to the power grid 3.

In this example, the server 200 may communicate with the charging station 100 and the power grid 3 through any communication mechanism/communication standard network, so as to implement information interaction. Specifically, the network may include a wireless network, a wired network, a combination of the wireless network and the wired network, etc. The wireless network includes, but is not limited to, a long term evolution (LTE) system, a 5th-generation (5G) system, a global system for mobile communication (GSM), Bluetooth (BT), wireless fidelity (Wi-Fi), radio frequency identification (RFID) technology, near field communication (NFC) technology, a code division multiple access (CDMA) network, a wideband code division multiple access (WCDMA) network, long range (Lora) technology or a Zigbee protocol. The wired network includes, but is not limited to, a bus interface such as a controller area network (CAN), a local interconnect network (LIN), RS-485, a universal asynchronous receiver/transmitter (UART), etc.

In this example, the charging station 100 may convert, through the electric energy router 10, the first alternating current that is transmitted by the power grid 3 into the first direct current, and transmit, through the plurality of charging ports, the first direct current to a corresponding vehicle power supply for charging. The charging station 100 may further transmit, through the charging port, the second direct current that is provided by the corresponding vehicle power supply to the electric energy router 10. The electric energy router 10 converts the second direct current into the second alternating current and transmits the second alternating current to the power grid 3 for peak load regulation. During a process of charging the corresponding vehicle power supply by the charging station 100 through each of the charging ports, the controller 21 of the electric energy router 10 of the charging station 100 may determine the power supply information, and then transmit, through the antenna 101, the power supply information to the server 200 for storage.

Optionally, the charging system may further include a photovoltaic generation system 400. The photovoltaic generation system 400 is connected to the photovoltaic interface of the electric energy router 10, and is configured to provide an alternating current for the electric energy router 10.

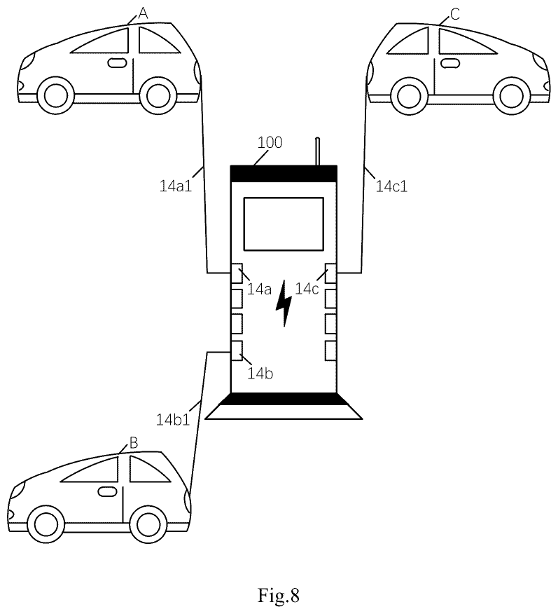

For example, reference may be made to FIGS. 2 and 8. FIG. 8 is a schematic diagram of charging a vehicle by a charging station according to an example of the disclosure. As shown in FIG. 8, the charging station 100 includes an electric energy router. A bidirectional power supply interface 2a of the electric energy router is connected to the charging port 14a, the bidirectional power supply interface 2b is connected to the charging port 14b, and the bidirectional power supply interface 2c is connected to the charging port 14c. The charging port 14a is connected to a vehicle power supply 1a of a vehicle A through a dedicated charging cable 14a1. The charging port 14b is connected to a vehicle power supply 1b of a vehicle B through a dedicated charging cable 14b1. The charging port 14c is connected to a vehicle power supply 1c of a vehicle C through a dedicated charging cable 14c1.

At a first moment, after the vehicle A and the vehicle B are connected to the electric energy router of the charging station 100, power at which the electric energy router provides the first direct current for the vehicle A is A1, and power at which the electric energy router provides the first direct current for the vehicle B is B1. In this case, the controller 21 detects that the current charging power equals a sum Y1 of A1 and B1. Since the current charging power Y1 is less than the power threshold Z, the electric energy router continues charging the vehicle A and the vehicle B.

Further, at a second moment, after the vehicle C is connected to the electric energy router of the charging station 100, the power at which the electric energy router provides the first direct current for the vehicle C is C1. In this case, the controller 21 detects that the current charging power equals a sum Y2 of A1, B1 and C1. The current charging power Y2 is greater than the power threshold Z, and the controller 21 detects that electric quantity information of the vehicle power supply 1a of the vehicle A is 100%, electric quantity information of the vehicle power supply 1b of the vehicle B is 90%, and electric quantity information of the vehicle power supply 1c of the vehicle C is 15%. The electric quantity information of the vehicle power supply 1a and the vehicle power supply 1b are both greater than 70% of the first electric quantity threshold. After the controller 21 sends a reverse power supply request signal to mobile phones of users corresponding to the vehicles A and B, the user of vehicle A agrees on reverse power supply through the corresponding mobile phone application program, that is, the reverse power supply signal is sent to the controller 21. The user of vehicle B does not reply to the power supply signal because of busy work. The controller 21 controls the inverter circuit 11a of the power conversion circuit 11 that corresponds to the reverse power supply signal to convert the second direct current that is provided by the vehicle power supply 1a into the second alternating current and transmit the second alternating current to the power grid 3. In addition, the controller 21 controls the inverter circuit 12a to reduce the charging power B1 of the vehicle B to the predetermined power B11, and controls the inverter circuit 13a to reduce the charging power C1 of the vehicle C to the predetermined power C11. Thus the controller 21 detects that the current charging power Y3 is less than the power threshold Z. Thus electric energy can be intelligently distributed, vehicle charging, and effective peak load regulation on the power grid are implemented, and high flexibility and applicability are achieved.

According to the example of the disclosure, the electric energy router is provided with the controller and the plurality of power conversion circuits. Each of the power conversion circuits converts the first alternating current that is transmitted by the power grid into the first direct current, and transmits the first direct current to the corresponding vehicle power supply for charging. The controller detects the first direct current that is provided by each of the power conversion circuits to determine the current charging power. The controller controls, in response to determining that the current charging power is greater than the power threshold and the reverse power supply signal is received, the power conversion circuit to convert the second direct current that is provided by the corresponding vehicle power supply into the second alternating current and transmit the second alternating current to the power grid. Thus electric energy can be intelligently distributed, vehicle charging, and effective peak load regulation on the power grid are implemented, and high flexibility and applicability are achieved.

The above examples are merely preferred examples of the disclosure and are not intended to limit the disclosure, and for those skilled in the art, various modifications and changes can be made to the disclosure. Any modification, equivalent substitution, improvement, etc. made within the spirit and principles of the disclosure should fall within the protection scope of the disclosure.

I/We claim:

1. An electric energy router, comprising:
a controller; and
a plurality of power conversion circuits connected to the controller, wherein each of the power conversion circuits is configured to convert a first alternating current that is transmitted by a power grid into a first direct current, and transmit the first direct current to a corresponding vehicle power supply for charging;
wherein the controller is configured to detect each of the first direct current to determine current charging power, control, in response to determining that the current charging power is greater than a power threshold and a reverse power supply signal is received, the power conversion circuit to convert a second direct current that is provided by the corresponding vehicle power supply into a second alternating current and transmit the second alternating current to the power grid.

2. The electric energy router according to claim 1, further comprising: a plurality of bidirectional power supply interfaces, wherein each of the power conversion circuits is connected to a corresponding bidirectional power supply interface, each of the power conversion circuits comprises:
an inverter circuit configured to convert the first alternating current into the first direct current, and transmit, through the corresponding bidirectional power supply interface, the first direct current to the corresponding vehicle power supply for charging, or convert the second direct current that is transmitted by the corresponding bidirectional power supply interface into the second alternating current, and the controller is further configured to detect the first direct current that is provided by each of the inverter circuits to determine the current charging power.

3. The electric energy router according to claim 2, wherein the controller is further configured to control, in response to determining that the current charging power is greater than the power threshold and the reverse power supply signal is not received, the inverter circuit to output a first direct current that has predetermined power, so as to cause the current charging power to be less than or equal to the power threshold.

4. The electric energy router according to claim 3, wherein each of the power conversion circuits further comprises:
a drive circuit connected to the inverter circuit and the controller;
wherein the controller is further configured to control the drive circuit to output a drive signal, to cause the inverter circuit to convert the first alternating current into a corresponding first direct current that has the predetermined power, or cause the inverter circuit to convert the second direct current into the second alternating current.

5. The electric energy router according to claim 4, further comprising:
a transformer that is connected to each of the inverter circuits and the power grid, and configured to perform voltage regulation on the first alternating current that is provided by the power grid, to be transmitted to each of the inverter circuits, or perform voltage regulation on the second alternating current that is provided by the inverter circuit, to be transmitted to the power grid.

6. The electric energy router according to claim 5, further comprising: a plurality of detection circuits, wherein each of the detection circuits is connected to the controller and a corresponding power conversion circuit, each of the detection circuits comprises:
a current detection circuit configured to detect current information of a first direct current that is output by a corresponding inverter circuit and transmit the current information to a signal amplification circuit;
a voltage detection circuit configured to detect voltage information of the first direct current that is output by the corresponding inverter circuit, and transmit the voltage information to the signal amplification circuit; and
the signal amplification circuit configured to amplify the current information and the voltage information, and transmit the current information and the voltage information that are amplified to the controller; and
the controller is further configured to determine the current charging power according to the current information and the voltage information that are amplified.

7. The electric energy router according to claim 6, wherein the plurality of power conversion circuits and the transformer are arranged on a first circuit board, and the controller and the plurality of detection circuits are arranged on a second circuit board.

8. The electric energy router according to claim 2, wherein the inverter circuit is a half-bridge circuit.

9. The electric energy router according to claim 6, wherein the controller is further configured to obtain power supply information and transmit the power supply information to a server, and the power supply information comprises at least one of the following information:
power supply duration of each of the bidirectional power supply interfaces;
the voltage information that is amplified;
the current information that is amplified; or,
the current charging power.

10. A charging station, comprising:
a monitor;
a plurality of charging ports, wherein each of the charging ports is configured to transmit a first direct current that is provided by an electric energy router to a corresponding vehicle power supply for charging, or transmit a second direct current that is provided by a corresponding vehicle power supply to an electric energy router;
an antenna configured to transmit power supply information of the electric energy router to a server; and
an electric energy router comprising:
a controller; and
a plurality of power conversion circuits connected to the controller, wherein each of the power conversion circuits is configured to convert a first alternating current that is transmitted by a power grid into a first direct current, and transmit the first direct current to a corresponding vehicle power supply for charging;
wherein the controller is configured to detect each of the first direct current to determine current charging power, control, in response to determining that the current charging power is greater than a power threshold and a reverse power supply signal is received, the power conversion circuit to convert a second direct current that is provided by the corresponding vehicle power supply into a second alternating current and transmit the second alternating current to the power grid.

11. The charging station according to claim 10, wherein the electric energy router further comprising: a plurality of bidirectional power supply interfaces, wherein each of the power conversion circuits is connected to a corresponding bidirectional power supply interface, each of the power conversion circuits comprises:
an inverter circuit configured to convert the first alternating current into the first direct current, and transmit, through the corresponding bidirectional power supply interface, the first direct current to the corresponding vehicle power supply for charging, or convert the second direct current that is transmitted by the corresponding bidirectional power supply interface into the second alternating current, and the controller is further configured to detect the first direct current that is provided by each of the inverter circuits to determine the current charging power.

12. The charging station according to claim 11, wherein the controller is further configured to control, in response to determining that the current charging power is greater than the power threshold and the reverse power supply signal is not received, the inverter circuit to output a first direct current that has predetermined power, so as to cause the current charging power to be less than or equal to the power threshold.

13. The charging station according to claim 12, wherein each of the power conversion circuits further comprises:
a drive circuit connected to the inverter circuit and the controller;
wherein the controller is further configured to control the drive circuit to output a drive signal, to cause the inverter circuit to convert the first alternating current into a corresponding first direct current that has the predetermined power, or cause the inverter circuit to convert the second direct current into the second alternating current.

14. The charging station according to claim 13, wherein the electric energy router further comprising:
a transformer that is connected to each of the inverter circuits and the power grid, and configured to perform voltage regulation on the first alternating current that is provided by the power grid, to be transmitted to each of the inverter circuits, or perform voltage regulation on the second alternating current that is provided by the inverter circuit, to be transmitted to the power grid.

15. The charging station according to claim 14, wherein the electric energy router further comprising: a plurality of detection circuits, wherein each of the detection circuits is connected to the controller and a corresponding power conversion circuit, each of the detection circuits comprises:
a current detection circuit configured to detect current information of a first direct current that is output by a corresponding inverter circuit and transmit the current information to a signal amplification circuit;
a voltage detection circuit configured to detect voltage information of the first direct current that is output by the corresponding inverter circuit, and transmit the voltage information to the signal amplification circuit; and
the signal amplification circuit configured to amplify the current information and the voltage information, and transmit the current information and the voltage information that are amplified to the controller; and
the controller is further configured to determine the current charging power according to the current information and the voltage information that are amplified.

16. The charging station according to claim 15, wherein the plurality of power conversion circuits and the transformer are arranged on a first circuit board, and the controller and the plurality of detection circuits are arranged on a second circuit board.

17. The charging station according to claim 11, wherein the inverter circuit is a half-bridge circuit.

18. The charging station according to claim 15, wherein the controller is further configured to obtain power supply information and transmit the power supply information to a server, and the power supply information comprises at least one of the following information:
power supply duration of each of the bidirectional power supply interfaces;
the voltage information that is amplified;
the current information that is amplified; or
the current charging power.
